(19) United States
(12) Patent Application Publication
(10) Pub. No.: US 2026/0161903 A1
(43) Pub. Date: Jun. 11, 2026

(54) PROTECTIVE MECHANISM AND CARD READER INCLUDING THE PROTECTIVE MECHANISM

(71) Applicant: CHENG UEI PRECISION INDUSTRY CO., LTD., New Taipei City (TW)

(72) Inventors: JIN-HUAI MO, Dong-Guan City (CN); WEI-JIAN WEN, Dong-Guan City (CN); XIAO-XIANG GUAN, Dong-Guan City (CN)

(21) Appl. No.: 19/246,681

(22) Filed: Jun. 23, 2025

(30) Foreign Application Priority Data
Dec. 6, 2024 (CN) 202423023772.5

(51) Int. Cl. G06K 7/00; H05K 5/02

(52) U.S. Cl. CPC G06K 7/0078; H05K 5/0204; H05K 5/0217

(57) ABSTRACT

A card reader includes a housing, a mounting portion and a protective mechanism. The housing is with an insertion opening penetrating through a front surface of the housing. The mounting portion is extended inwardly from a periphery wall of the insertion opening. The protective mechanism is mounted in the housing, and the protective mechanism is fastened to the mounting portion. The protective mechanism includes a fixing structure, a penetrating slot, a first dust-proof sheet, a second dust-proof sheet, a rigid first guiding plate and a rigid second guiding plate. The penetrating slot longitudinally penetrates through a middle of the fixing structure. The first dust-proof sheet extends downward. The second dust-proof sheet extends upward. The rigid first guiding plate is positioned at a free end of the first dust-proof sheet. The rigid second guiding plate is positioned at a free end of the second dust-proof sheet.

### CROSS REFERENCE TO RELATED APPLICATIONS

The present application is based on, and claims priority from, China Patent Application No. 202423023772.5, filed December 6, 2024, the disclosure of which is hereby incorporated by reference herein in its entirety.

### BACKGROUND OF THE INVENTION

### Field of the Invention

The present invention generally relates to a protective mechanism, and more particularly to a card reader including a protective mechanism which is capable of preventing foreign objects from entering an interior of the card reader and enhancing a card insertion and withdrawal stability.

### Description of Related Art

Generally, credit cards, debit cards, transportation cards or health insurance cards are used in daily lives. Each of the credit cards, the debit cards, the transportation cards and the health insurance cards contains a chip. The credit cards, the debit cards, the transportation cards or the health insurance cards are inserted into automatic teller machines (ATMs), point of sale (POS) machines, chip readers or other card readers to store and access data information of the chips of the credit cards, the debit cards, the transportation cards or the health insurance cards. Nevertheless, foreign objects which are dust, liquids and other foreign substances may enter an interior of the card reader through a card insertion slot of the card reader, so that a component of the card reader is damaged, and the card reader has a poor chip contact. As a result, a usage lifespan of the card reader is affected.

An IC (Integrated Circuit) card holder with a protective function includes a holder body and a semi-closed slot body. The holder body has a card insertion opening and an internal installation space. The semi-closed slot body has an opening end and a closing end. The opening end is installed at the holder body. An interior of the semi-closed slot body has a card slot. A mouth of the card slot is opened at the opening end, and the mouth of the card slot is communicated with the card insertion opening. The closing end extends into the internal installation space, so that the card slot is separated from the internal installation space, and external debris is prevented from entering the internal installation space through the card slot to cause a damage of an internal part. Nonetheless, in this structure design, a barrier structure is without being disposed between the card slot and the card insertion opening, the external debris may enter the internal installation space from the card insertion opening and the external debris may be accumulated inside the card slot, consequently, a predicament situation of a chip card reading failure is caused.

A conventional card reader includes an upper shell with a card insertion channel, a lower shell combined with the upper shell, and a protective mechanism disposed between the upper shell and the lower shell. The protective mechanism includes a protective shell and a dust-proof sheet. The protective shell defines a penetrating slot penetrating through a front surface and a rear surface of the protective shell. The penetrating slot is communicated with the card insertion channel. One end of the protective shell near the card insertion channel is an insertion end, and the other end of the protective shell is an outlet end. The dust-proof sheet is disposed at the outlet end. The dust-proof sheet includes an upper dust-proof sheet and a lower dust-proof sheet. When a card is inserted into the conventional card reader through the card insertion channel, the upper dust-proof sheet and the lower dust-proof sheet are deformed towards an interior of the conventional card reader. After the card is removed, the upper dust-proof sheet and the lower dust-proof sheet are automatically reset, a bottom end of the upper dust-proof sheet contacts with a top end of the lower dust-proof sheet, the upper dust-proof sheet and the lower dust-proof sheet cover the outlet end to prevent the foreign objects from entering the interior of the conventional card reader.

However, in this structure design, the dust-proof sheet is only formed by adhering a backing adhesive to the outlet end, after the dust-proof sheet is used for a long time, the dust-proof sheet may skew, deform or fall off on account of a descending viscosity of the backing adhesive. Additionally, the dust-proof sheet is made of a material that is flexibly deformable and is automatically recoverable, the dust-proof sheet automatically generates a larger frictional resistance when the card passes through the dust-proof sheet, so a smoothness of the card is affected at the time of inserting the card into the conventional card reader and removing the card from the conventional card reader.

In view of the above-mentioned shortcomings, it is essential to provide an innovative card reader including an innovative protective mechanism which is capable of preventing the foreign objects from entering an interior of the innovative card reader and enhancing a card insertion and withdrawal stability.

### BRIEF SUMMARY OF THE INVENTION

An object of the present invention is to provide a protective mechanism. The protective mechanism includes a fixing structure, a penetrating slot, a flexibly deformable first dust-proof sheet, a flexibly deformable second dust-proof sheet, a rigid first guiding plate and a rigid second guiding plate. The fixing structure has an upper inner end surface and a lower inner end surface which are opposite to each other. The penetrating slot longitudinally penetrates through a middle of the fixing structure, and the penetrating slot is disposed as an elongated opening slot. The penetrating slot is located between the upper inner end surface and the lower inner end surface. The flexibly deformable first dust-proof sheet is disposed at the upper inner end surface of the fixing structure. The first dust-proof sheet extends downward. The flexibly deformable second dust-proof sheet is disposed at the lower inner end surface of the fixing structure. The second dust-proof sheet extends upward and towards the first dust-proof sheet. A free end of the second dust-proof sheet faces a free end of the first dust-proof sheet. An interval is maintained between the free end of the first dust-proof sheet and the free end of the second dust-proof sheet. The rigid first guiding plate is positioned at the free end of the first dust-proof sheet. The rigid second guiding plate is positioned at the free end of the second dust-proof sheet. A free end of the first guiding plate abuts against or breaks away from a free end of the second guiding plate.

Another object of the present invention is to provide a card reader which is capable of preventing foreign objects from entering an interior of the card reader and enhancing a card insertion and withdrawal stability. The card reader includes a housing, a mounting portion and a protective mechanism. The housing is with an insertion opening penetrating through a front surface of the housing. The mounting portion is extended inwardly and towards an interior of the housing from a periphery wall of the insertion opening. The protective mechanism is mounted in the housing, and the protective mechanism is fastened to the mounting portion. The protective mechanism includes a fixing structure, a penetrating slot, a flexibly deformable first dust-proof sheet, a flexibly deformable second dust-proof sheet, a rigid first guiding plate and a rigid second guiding plate. The fixing structure has an upper inner end surface and a lower inner end surface which are opposite to each other. The penetrating slot longitudinally penetrates through a middle of the fixing structure. A peripheral surface of the penetrating slot defines an inner wall surface. The penetrating slot extends between the upper inner end surface and the lower inner end surface. An outer surface of the mounting portion is combined with the inner wall surface. The flexibly deformable first dust-proof sheet is disposed at the upper inner end surface of the fixing structure. The first dust-proof sheet extends downward. The flexibly deformable second dust-proof sheet is disposed at the lower inner end surface of the fixing structure. The second dust-proof sheet extends upward and towards the first dust-proof sheet. A free end of the second dust-proof sheet faces a free end of the first dust-proof sheet. An interval is maintained between the free end of the first dust-proof sheet and the free end of the second dust-proof sheet. The rigid first guiding plate is positioned at the free end of the first dust-proof sheet. The rigid second guiding plate is positioned at the free end of the second dust-proof sheet. A free end of the first guiding plate abuts against or breaks away from a free end of the second guiding plate.

Another object of the present invention is to provide a card reader. The card reader includes a housing, a mounting portion and a protective mechanism. The housing is with an insertion opening penetrating through a front surface of the housing. The mounting portion is extended inwardly and towards an interior of the housing from a periphery wall of the insertion opening. The protective mechanism is mounted in the housing, and the protective mechanism is fastened to the mounting portion. The protective mechanism includes a fixing structure, a penetrating slot, a flexibly deformable first dust-proof sheet, a flexibly deformable second dust-proof sheet, a rigid first guiding plate and a rigid second guiding plate. The fixing structure has an upper inner end surface and a lower inner end surface which are opposite to each other. The penetrating slot longitudinally penetrates through a middle of the fixing structure. The penetrating slot is communicated with the insertion opening. A peripheral surface of the penetrating slot defines an inner wall surface. The penetrating slot extends between the upper inner end surface and the lower inner end surface. An outer surface of the mounting portion is combined with the inner wall surface. The flexibly deformable first dust-proof sheet is disposed at the upper inner end surface of the fixing structure. The first dust-proof sheet extends downward. The flexibly deformable second dust-proof sheet is disposed at the lower inner end surface of the fixing structure. The second dust-proof sheet extends upward and towards the first dust-proof sheet. A free end of the second dust-proof sheet faces a free end of the first dust-proof sheet. An interval is maintained between the free end of the first dust-proof sheet and the free end of the second dust-proof sheet. The rigid first guiding plate is positioned at the free end of the first dust-proof sheet. The rigid second guiding plate is positioned at the free end of the second dust-proof sheet. The first dust-proof sheet and the second dust-proof sheet are flexibly deformable. The first guiding plate and the second guiding plate are flippable with respect to the penetrating slot to cover or uncover the penetrating slot.

As described above, the protective mechanism is provided in the present invention to be installed in the insertion opening of the card reader, the protective mechanism includes the fixing structure, and the first guiding plate and the second guiding plate flippable with respect to the penetrating slot to cover or uncover the penetrating slot, the fixing structure defines the penetrating slot longitudinally penetrating through a front surface and a rear surface of the fixing structure, and the penetrating slot is aligned with the insertion opening, the first guiding plate and the second guiding plate cover the penetrating slot, so the insertion opening is sealed up to block external foreign objects from entering an interior of the card reader through the insertion opening. Furthermore, the upper inner end surface and the lower inner end surface of the fixing structure extend towards the penetrating slot to form the first dust-proof sheet and the second dust-proof sheet, one end of the first guiding plate is provided with a first embedding portion embedded in the free end of the first dust-proof sheet, and one end of the second guiding plate is provided with a second embedding portion embedded in the free end of the second dust-proof sheet, therefore, a bonding force among the first guiding plate, the fixing structure and the second guiding plate is enhanced, and a stability of inserting and removing the card is improved.

### BRIEF DESCRIPTION OF THE DRAWINGS

The present invention will be apparent to those skilled in the art by reading the following description, with reference to the attached drawings, in which:

FIG. 1 is a perspective view of a protective mechanism according to the present invention;

FIG. 2 is an enlarged view of an encircled portion A of FIG. 1;

FIG. 3 is an exploded view of the protective mechanism according to the present invention;

FIG. 4 is a schematic diagram of a card reader showing that a card is without being inserted into the card reader;

FIG. 5 is a partially enlarged cross-sectional view of the card reader along a line I-I of FIG. 4;

FIG. 6 is a schematic diagram of the card reader showing that the card is inserted into the card reader; and

FIG. 7 is a partially enlarged cross-sectional view of the card reader along a line II-II of FIG. 6.

### DETAILED DESCRIPTION OF THE INVENTION

In order to provide a detailed explanation of a technical content, structural features, achieved objectives and effects of the present invention, following examples are provided with accompanying diagrams for a detailed illustration.

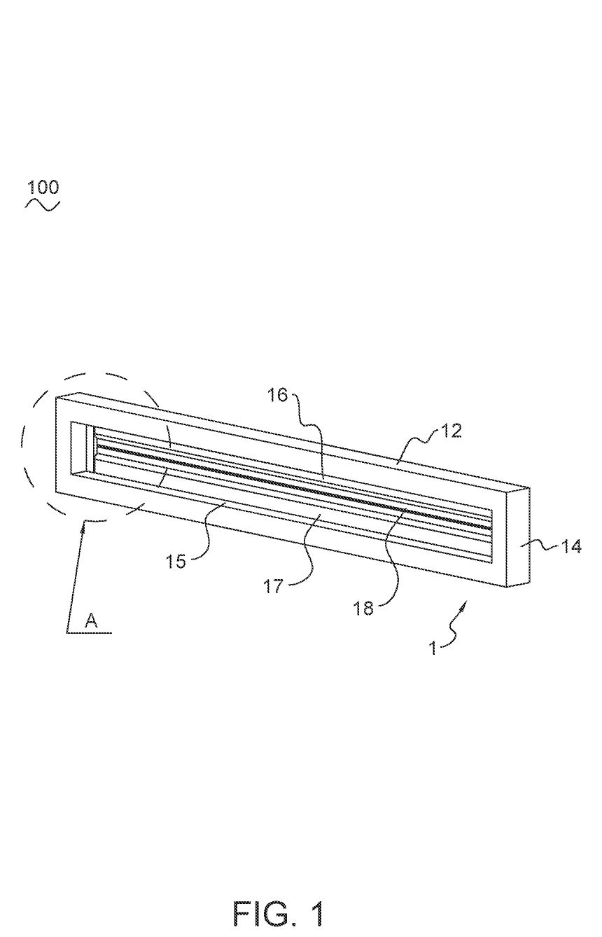

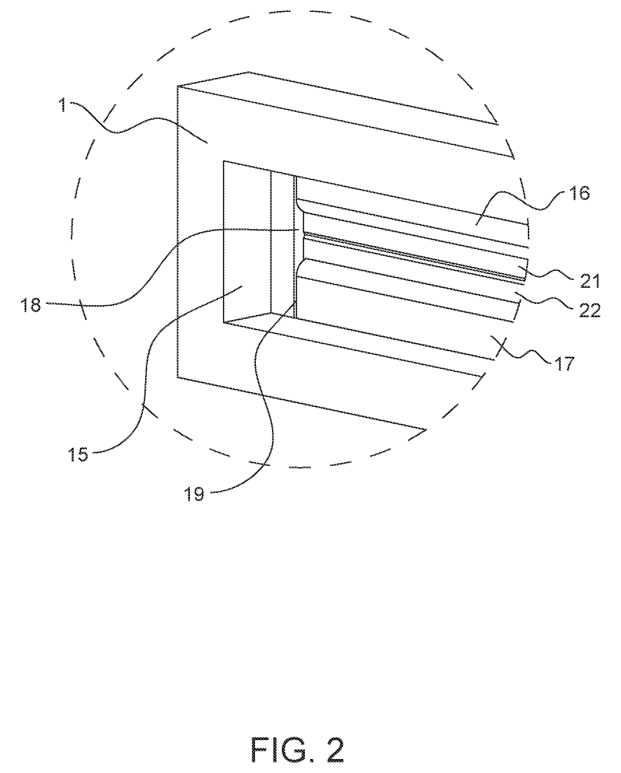

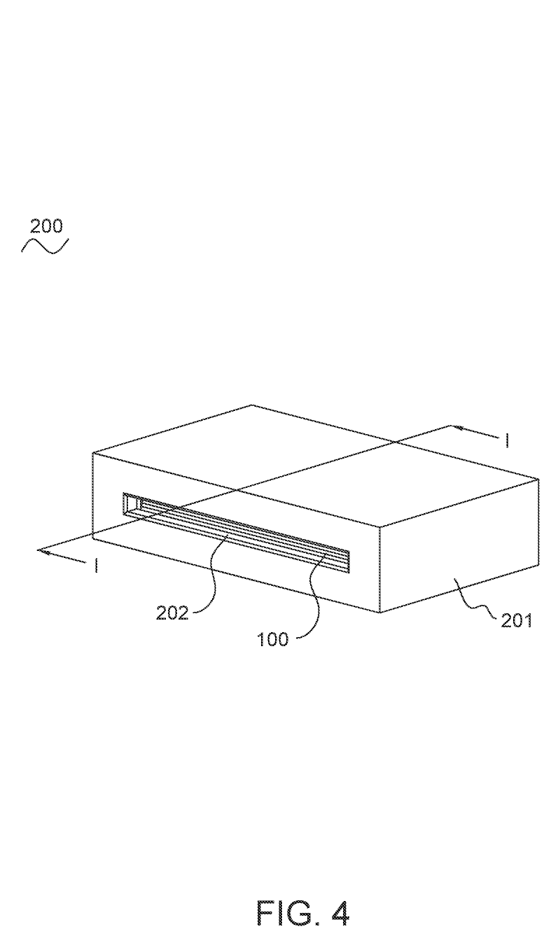

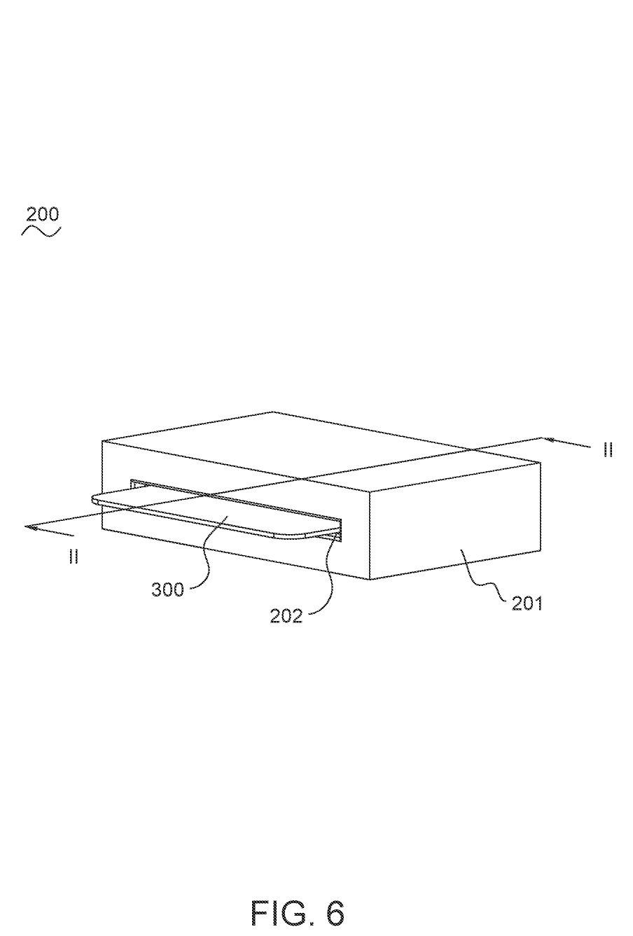

Referring to FIG. 1 to FIG. 7, a protective mechanism 100, and a card reader 200 including the protective mechanism 100 according to the present invention are shown. The protective mechanism 100 is installed in the card reader 200. The card reader 200 includes a housing 201 with an insertion opening 202 penetrating through a front surface of the housing 201, and the protective mechanism 100 housed inside the card reader 200. The protective mechanism 100 is positioned to an inner end of the insertion opening 202.

The protective mechanism 100 includes a fixing structure 1, a flexibly deformable first dust-proof sheet 16, a second dust-proof sheet 17, a rigid first guiding plate 21 and a rigid second guiding plate 22. A middle of a front of the fixing structure 1 is opened freely. The fixing structure 1 is shown as a hollow rectangular shape. The fixing structure 1 has an upper inner end surface 102 and a lower inner end surface 103 which are opposite to each other. The fixing structure 1 defines a penetrating slot 18 longitudinally penetrating through a middle of the fixing structure 1. The penetrating slot 18 penetrates through middles of a front surface and a rear surface of the fixing structure 1. The penetrating slot 18 is disposed transversely, and the penetrating slot 18 is shown as an elongated shape. The penetrating slot 18 is disposed as an elongated opening slot. The penetrating slot 18 is communicated with the insertion opening 202. The penetrating slot 18 is aligned with the insertion opening 202. The penetrating slot 18 extends between the upper inner end surface 102 and the lower inner end surface 103. The penetrating slot 18 is located between the upper inner end surface 102 and the lower inner end surface 103.

The flexibly deformable first dust-proof sheet 16 is disposed at the upper inner end surface 102 of the fixing structure 1. The first dust-proof sheet 16 extends downward. The flexibly deformable second dust-proof sheet 17 is disposed at the lower inner end surface 103 of the fixing structure 1. The second dust-proof sheet 17 extends upward and towards the first dust-proof sheet 16. A free end of the second dust-proof sheet 17 faces a free end of the first dust-proof sheet 16. An interval is maintained between the free end of the first dust-proof sheet 16 and the free end of the second dust-proof sheet 17.

The first dust-proof sheet 16 and the second dust-proof sheet 17 are flexible elements. The upper inner end surface 102 and the lower inner end surface 103 of the fixing structure 1 extend towards the penetrating slot 18 to form the first dust-proof sheet 16 and the second dust-proof sheet 17. A rear of an inner upper wall and a rear of an inner lower wall of the penetrating slot 18 extend towards each other to form the first dust-proof sheet 16 and the second dust-proof sheet 17 in the penetrating slot 18.

The first guiding plate 21 and the second guiding plate 22 are rigid elements. The rigid first guiding plate 21 is positioned at the free end of the first dust-proof sheet 16, and the rigid second guiding plate 22 is positioned at the free end of the second dust-proof sheet 17. The first dust-proof sheet 16 and the second dust-proof sheet 17 are symmetrically arranged with respect to a center line of the penetrating slot 18. The first guiding plate 21 and the second guiding plate 22 face each other. The first guiding plate 21 positioned at the first dust-proof sheet 16 and the second guiding plate 22 positioned at the second dust-proof sheet 17 abut each other, so the penetrating slot 18 is sealed up to prevent external foreign objects from entering an interior of the card reader 200 through the insertion opening 202.

Referring to FIG. 1 to FIG. 3, the fixing structure 1 has a top wall 12 located at an upper portion of the fixing structure 1, a bottom wall 13 located at a lower portion of the fixing structure 1, and two side walls 14 located at two opposite sides of the fixing structure 1. The first dust-proof sheet 16 is extended inward and towards the penetrating slot 18 from an inner surface of the top wall 12 of the fixing structure 1, and the first dust-proof sheet 16 partially covers the penetrating slot 18. The second dust-proof sheet 17 is extended inward and towards the penetrating slot 18 from an inner surface of the bottom wall 13 of the fixing structure 1. The second dust-proof sheet 17 partially covers the penetrating slot 18.

The fixing structure 1 defines two pairs of cutting slots 19 extending to the penetrating slot 18. Two opposite sides of the first dust-proof sheet 16 define one pair of the cutting slots 19, and two opposite sides of the second dust-proof sheet 17 define the other pair of the cutting slots 19. Each cutting slot 19 is communicated with the penetrating slot 18. The first dust-proof sheet 16 and the second dust-proof sheet 17 are separated from the two side walls 14 of the fixing structure 1. The cutting slots 19 of the fixing structure 1 are designed to improve a deformation force of the first dust-proof sheet 16 and a deformation force of the second dust-proof sheet 17.

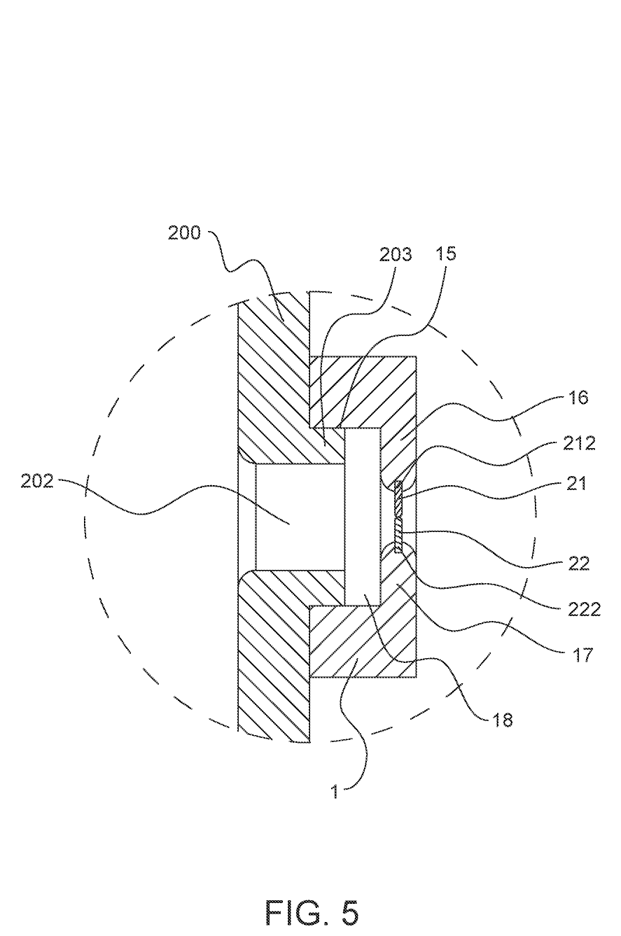

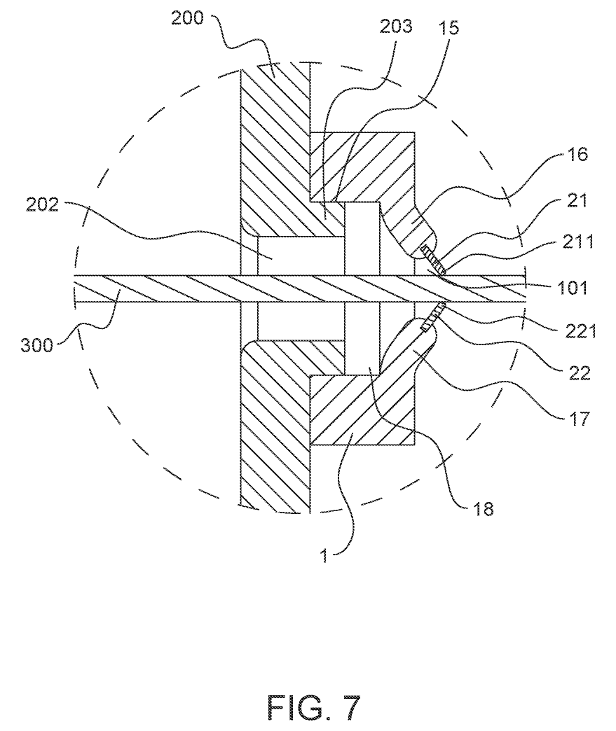

Referring to FIG. 5 and FIG. 7, a free end of the first guiding plate 21 abuts against or breaks away from a free end of the second guiding plate 22. The first dust-proof sheet 16 and the second dust-proof sheet 17 are flexibly deformable. The first guiding plate 21 and the second guiding plate 22 are flippable with respect to the penetrating slot 18 to cover or uncover the penetrating slot 18 by actions of the flexibly deformable first dust-proof sheet 16 and the flexibly deformable second dust-proof sheet 17.

When a card 300 is inserted into the insertion opening 202 of the card reader 200, the card 300 pushes against a contacting area between the first guiding plate 21 and the second guiding plate 22 along a card insertion direction, and the first guiding plate 21 and the second guiding plate 22 flip towards the interior of the card reader 200. The first dust-proof sheet 16 and the second dust-proof sheet 17 have flexible deformation characteristics, so the first dust-proof sheet 16 and the second dust-proof sheet 17 also flip towards the interior of the card reader 200 along with the first guiding plate 21 and the second guiding plate 22. At this moment, the first guiding plate 21 and the second guiding plate 22 are separated from each other to uncover the penetrating slot 18, so a passage 101 is opened between the first guiding plate 21 and the second guiding plate 22, the card 300 passes through the passage 101, and the card 300 enters the interior of the card reader 200. At this point, the first dust-proof sheet 16 and the second dust-proof sheet 17 are in flexible deformation statuses. The first guiding plate 21 and the second guiding plate 22 have rigidity performances, so the first guiding plate 21 and the second guiding plate 22 are without flexible deformations.

After the card 300 is removed, the first guiding plate 21 and the second guiding plate 22 move towards the insertion opening 202 to make the first guiding plate 21 and the second guiding plate 22 close to the insertion opening 202, and the first guiding plate 21 and the second guiding plate 22 are restored to original positions, so a bottom end of the first guiding plate 21 and a top end of the second guiding plate 22 abut each other to cover the penetrating slot 18. At the moment, the first dust-proof sheet 16, the second dust-proof sheet 17, the first guiding plate 21 and the second guiding plate 22 cover the penetrating slot 18, so the insertion opening 202 is sealed up to block the external foreign objects from entering the interior of the card reader 200 through the insertion opening 202.

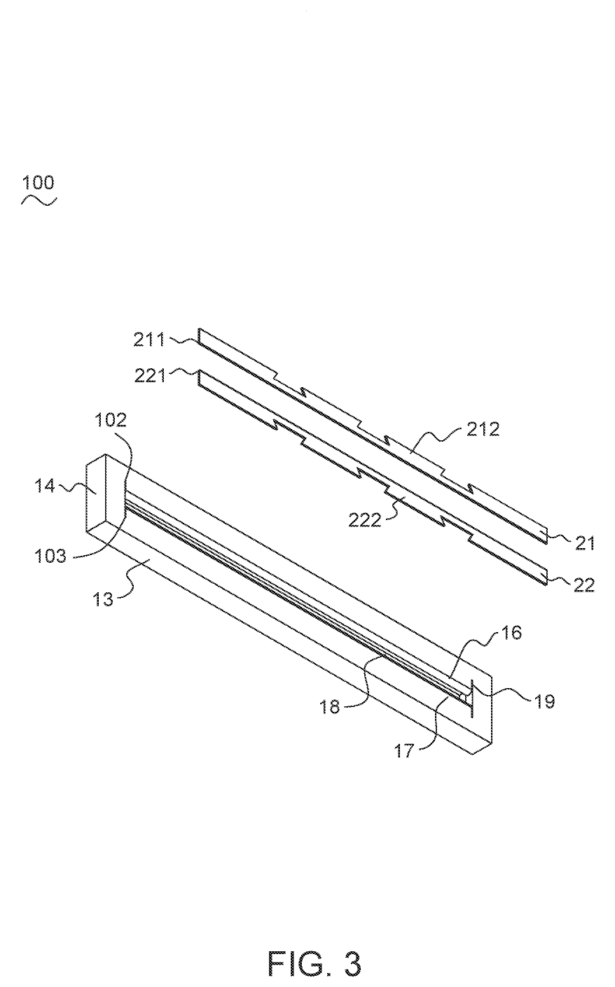

Referring to FIG. 3 and FIG. 7, in the present invention, the bottom end of the first guiding plate 21 that contacts the second guiding plate 22 is provided with a first guiding portion 211, and the top end of the second guiding plate 22 that contacts the first guiding plate 21 is provided with a second guiding portion 221. The free end of the first guiding plate 21 has the first guiding portion 211. The free end of the second guiding plate 22 has the second guiding portion 221. The first guiding portion 211 abuts against or breaks away from the second guiding portion 221.

When the card 300 passes between the first guiding plate 21 and the second guiding plate 22, an upper surface and a lower surface of the card 300 respectively contact with the first guiding portion 211 and the second guiding portion 221. The first guiding plate 21 and the second guiding plate 22 are made of metal materials. Because a friction coefficient of the metal material is lower than a friction coefficient of a flexible soft material, a benefit is provided for a reduction of a friction resistance force at the time of inserting and removing the card 300. Additionally, the first guiding portion 211 and the second guiding portion 221 are configured as arc structures, and the first guiding portion 211 and the second guiding portion 221 are arched towards each other, so that an insertion and a removal of the card 300 are smoother. In a concrete implementation, the card reader 200 is without being limited to this structure.

Referring to FIG. 3 and FIG. 5, the fixing structure 1 is made of elastic soft colloid materials, such as rubber or silicone. The first guiding plate 21 and the second guiding plate 22 are embedded into the first dust-proof sheet 16 and the second dust-proof sheet 17, respectively by means of an embedded injection molding way. One end of the first guiding plate 21 is provided with a first embedding portion 212, and the first embedding portion 212 is embedded in the free end of the first dust-proof sheet 16. One end of the second guiding plate 22 is provided with a second embedding portion 222, and the second embedding portion 222 is embedded in the free end of the second dust-proof sheet 17. The first embedding portion 212 and the second embedding portion 222 are configured as multiple serrated structures, therefore, a bonding force between the first guiding plate 21 and the first dust-proof sheet 16 and a bonding force between the second guiding plate 22 and the second dust-proof sheet 17 are enhanced, correspondingly, a bonding force among the first guiding plate 21, the fixing structure 1 and the second guiding plate 22 is enhanced, and a stability of inserting and removing the card 300 is improved.

Referring to FIG. 1 to FIG. 7, in order to install the protective mechanism 100 inside the card reader 200, a peripheral surface of the penetrating slot 18 of the fixing structure 1 defines an inner wall surface 15. An inner wall of the card reader 200 is provided with a mounting portion 203. The mounting portion 203 is extended inwardly and towards an interior of the housing 201 of the card reader 200 from a periphery wall of the insertion opening 202. The protective mechanism 100 is mounted in the housing 201, and the protective mechanism 100 is fastened to the mounting portion 203. The mounting portion 203 is adhered to the inner wall surface 15, and the mounting portion 203 is combined with the inner wall surface 15. In the concrete implementation, an outer surface of the mounting portion 203 is adhered to the inner wall surface 15 by use of glue or a backing adhesive, and the outer surface of the mounting portion 203 is combined with the inner wall surface 15, so that the protective mechanism 100 is located to the card reader 200, and the protective mechanism 100 is fastened to the card reader 200.

As described above, the protective mechanism 100 is provided in the present invention to be installed in the insertion opening 202 of the card reader 200, the protective mechanism 100 includes the fixing structure 1, and the first guiding plate 21 and the second guiding plate 22 flippable with respect to the penetrating slot 18 to cover or uncover the penetrating slot 18, the fixing structure 1 defines the penetrating slot 18 longitudinally penetrating through the front surface and the rear surface of the fixing structure 1, and the penetrating slot 18 is aligned with the insertion opening 202, the first guiding plate 21 and the second guiding plate 22 cover the penetrating slot 18, so the insertion opening 202 is sealed up to block the external foreign objects from entering the interior of the card reader 200 through the insertion opening 202. Furthermore, the upper inner end surface 102 and the lower inner end surface 103 of the fixing structure 1 extend towards the penetrating slot 18 to form the first dust-proof sheet 16 and the second dust-proof sheet 17, the one end of the first guiding plate 21 is provided with the first embedding portion 212 embedded in the free end of the first dust-proof sheet 16, and the one end of the second guiding plate 22 is provided with the second embedding portion 222 embedded in the free end of the second dust-proof sheet 17, therefore, the bonding force among the first guiding plate 21, the fixing structure 1 and the second guiding plate 22 is enhanced, and the stability of inserting and removing the card 300 is improved.

What is claimed is:

1. A protective mechanism, comprising:
a fixing structure having an upper inner end surface and a lower inner end surface which are opposite to each other;
a penetrating slot longitudinally penetrating through a middle of the fixing structure, and the penetrating slot being disposed as an elongated opening slot, the penetrating slot being located between the upper inner end surface and the lower inner end surface;
a flexibly deformable first dust-proof sheet disposed at the upper inner end surface of the fixing structure, the first dust-proof sheet extending downward;
a flexibly deformable second dust-proof sheet disposed at the lower inner end surface of the fixing structure, the second dust-proof sheet extending upward and towards the first dust-proof sheet, a free end of the second dust-proof sheet facing a free end of the first dust-proof sheet, an interval being maintained between the free end of the first dust-proof sheet and the free end of the second dust-proof sheet;
a rigid first guiding plate positioned at the free end of the first dust-proof sheet; and
a rigid second guiding plate positioned at the free end of the second dust-proof sheet, a free end of the first guiding plate abutting against or breaking away from a free end of the second guiding plate.

2. The protective mechanism as claimed in claim 1, wherein the fixing structure is shown as a hollow rectangular shape, the fixing structure has a top wall located at an upper portion of the fixing structure, a bottom wall located at a lower portion of the fixing structure, and two side walls located at two opposite sides of the fixing structure, the first dust-proof sheet is extended inward from an inner surface of the top wall of the fixing structure, the second dust-proof sheet is extended inward from an inner surface of the bottom wall of the fixing structure.

3. The protective mechanism as claimed in claim 2, wherein the fixing structure defines two pairs of cutting slots extending to the penetrating slot, two opposite sides of the first dust-proof sheet define one pair of the cutting slots, and two opposite sides of the second dust-proof sheet define the other pair of the cutting slots, each cutting slot is communicated with the penetrating slot, the first dust-proof sheet and the second dust-proof sheet are separated from the two side walls of the fixing structure via the cutting slots.

4. The protective mechanism as claimed in claim 1, wherein the free end of the first guiding plate has a first guiding portion, the free end of the second guiding plate has a second guiding portion, the first guiding portion abuts against or breaks away from the second guiding portion.

5. The protective mechanism as claimed in claim 4, wherein the first guiding portion and the second guiding portion are configured as arc structures.

6. The protective mechanism as claimed in claim 1, wherein one end of the first guiding plate is provided with a first embedding portion, and the first embedding portion is embedded in the free end of the first dust-proof sheet, one end of the second guiding plate is provided with a second embedding portion, and the second embedding portion is embedded in the free end of the second dust-proof sheet.

7. The protective mechanism as claimed in claim 6, wherein the first embedding portion and the second embedding portion are configured as multiple serrated structures.

8. A card reader, comprising:
a housing with an insertion opening penetrating through a front surface of the housing;
a mounting portion extended inwardly and towards an interior of the housing from a periphery wall of the insertion opening; and
a protective mechanism mounted in the housing, and the protective mechanism being fastened to the mounting portion, the protective mechanism having:
a fixing structure having an upper inner end surface and a lower inner end surface which are opposite to each other;
a penetrating slot longitudinally penetrating through a middle of the fixing structure, a peripheral surface of the penetrating slot defining an inner wall surface, the penetrating slot extending between the upper inner end surface and the lower inner end surface, an outer surface of the mounting portion being combined with the inner wall surface;
a flexibly deformable first dust-proof sheet disposed at the upper inner end surface of the fixing structure, the first dust-proof sheet extending downward;
a flexibly deformable second dust-proof sheet disposed at the lower inner end surface of the fixing structure, the second dust-proof sheet extending upward and towards the first dust-proof sheet, a free end of the second dust-proof sheet facing a free end of the first dust-proof sheet, an interval being maintained between the free end of the first dust-proof sheet and the free end of the second dust-proof sheet;
a rigid first guiding plate positioned at the free end of the first dust-proof sheet; and
a rigid second guiding plate positioned at the free end of the second dust-proof sheet, a free end of the first guiding plate abutting against or breaking away from a free end of the second guiding plate.

9. The card reader as claimed in claim 8, wherein the fixing structure is shown as a hollow rectangular shape, the fixing structure has a top wall located at an upper portion of the fixing structure, a bottom wall located at a lower portion of the fixing structure, and two side walls located at two opposite sides of the fixing structure, the first dust-proof sheet is extended inward from an inner surface of the top wall of the fixing structure, the second dust-proof sheet is extended inward from an inner surface of the bottom wall of the fixing structure, the fixing structure defines two pairs of cutting slots extending to the penetrating slot, two opposite sides of the first dust-proof sheet define one pair of the cutting slots, and two opposite sides of the second dust-proof sheet define the other pair of the cutting slots, each cutting slot is communicated with the penetrating slot, the first dust-proof sheet and the second dust-proof sheet are separated from the two side walls of the fixing structure via the cutting slots.

10. The card reader as claimed in claim 8, wherein one end of the first guiding plate is provided with a first embedding portion, and the first embedding portion is embedded in the free end of the first dust-proof sheet, one end of the second guiding plate is provided with a second embedding portion, and the second embedding portion is embedded in the free end of the second dust-proof sheet.

11. The card reader as claimed in claim 8, wherein the free end of the first guiding plate has a first guiding portion, the free end of the second guiding plate has a second guiding portion, the first guiding portion abuts against or breaks away from the second guiding portion.

12. The card reader as claimed in claim 11, wherein the first guiding portion and the second guiding portion are configured as arc structures.

13. The card reader as claimed in claim 8, wherein the outer surface of the mounting portion is adhered to the inner wall surface by use of glue.

14. The card reader as claimed in claim 8, wherein the outer surface of the mounting portion is adhered to the inner wall surface by use of a backing adhesive.

15. A card reader, comprising:
a housing with an insertion opening penetrating through a front surface of the housing;
a mounting portion extended inwardly and towards an interior of the housing from a periphery wall of the insertion opening; and
a protective mechanism mounted in the housing, and the protective mechanism being fastened to the mounting portion, the protective mechanism having:
a fixing structure having an upper inner end surface and a lower inner end surface which are opposite to each other;
a penetrating slot longitudinally penetrating through a middle of the fixing structure, the penetrating slot being communicated with the insertion opening, a peripheral surface of the penetrating slot defining an inner wall surface, the penetrating slot extending between the upper inner end surface and the lower inner end surface, an outer surface of the mounting portion being combined with the inner wall surface;
a flexibly deformable first dust-proof sheet disposed at the upper inner end surface of the fixing structure, the first dust-proof sheet extending downward;
a flexibly deformable second dust-proof sheet disposed at the lower inner end surface of the fixing structure, the second dust-proof sheet extending upward and towards the first dust-proof sheet, a free end of the second dust-proof sheet facing a free end of the first dust-proof sheet, an interval being maintained between the free end of the first dust-proof sheet and the free end of the second dust-proof sheet;
a rigid first guiding plate positioned at the free end of the first dust-proof sheet; and
a rigid second guiding plate positioned at the free end of the second dust-proof sheet;
wherein the first dust-proof sheet and the second dust-proof sheet are flexibly deformable, the first guiding plate and the second guiding plate are flippable with respect to the penetrating slot to cover or uncover the penetrating slot.

16. The card reader as claimed in claim 15, wherein the penetrating slot is aligned with the insertion opening.
